(19) United States
(12) Patent Application Publication
(10) Pub. No.: US 2025/0133854 A1
(43) Pub. Date: Apr. 24, 2025

(54) IMAGE SENSING DEVICE

(71) Applicant: SK hynix Inc., Icheon-si (KR)

(72) Inventor: Sung Wook CHO, Icheon-si (KR)

(21) Appl. No.: 18/599,771

(22) Filed: Mar. 8, 2024

(30) Foreign Application Priority Data
Oct. 23, 2023 (KR) 10-2023-0142091

(51) Int. Cl. H01L 27/146

(52) U.S. Cl. CPC H10F 39/807; H10F 39/802; H10F 39/8053; H10F 39/8063

(57) ABSTRACT

Disclosed is an image sensing device including a pixel array including a unit pixel including sub-pixels. A first isolation region is disposed in an edge region of a sub-pixel, a second isolation region extends from the first isolation region to a central portion of the sub-pixel. The second isolation region includes: a first inner isolation region protruding in a first direction from one region of the first isolation region to the central portion of the sub-pixel, and a second inner isolation region formed on a same straight line as the first inner isolation region and protruding in a second direction from another region of the first isolation region to the central portion of the sub-pixel. A first grid is formed in an upper region located above a region between the first inner isolation region and the second inner isolation region, and the first grid includes an air layer.

### CROSS-REFERENCE TO RELATED APPLICATION(S)

This patent document claims the priority and benefits of Korean Patent Application No. 10-2023-0142091, filed on Oct. 23, 2023, which is incorporated by reference in its entirety as part of the disclosure of this patent document.

### TECHNICAL FIELD

Various embodiments of the disclosed technology relate to an image sensing device, and more particularly, to an image sensing device capable of reducing an optical loss.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device capable of reducing an optical loss, by forming an air grid, which has no light absorbing material, in an inner isolation region.

In one aspect, an image sensing device is provided to include: a pixel array that includes a plurality of unit pixels, a unit pixel in the pixel array may include a plurality of sub-pixels, a first isolation region may be disposed in an edge region of a sub-pixel, a second isolation region may extend from the first isolation region to a central portion of the sub-pixel, the second isolation region may include: a first inner isolation region protruding in a first direction from one region of the first isolation region to the central portion of the sub-pixel, and a second inner isolation region formed on a same straight line as the first inner isolation region and protruding in a second direction from another region of the first isolation region to the central portion of the sub-pixel, a first grid may be formed in an upper region that is located above a region between the first inner isolation region and the second inner isolation region, and the first grid may include an air layer.

In some implementations, the sub-pixel may include: the first inner isolation region, the second inner isolation region, a color filter formed over the first inner isolation region and the second inner isolation region, and a microlens formed over the color filter, and the first grid may be formed in a central region of the color filter.

In some implementations, a photodiode may be disposed below the first grid.

In some implementations, a second grid may be disposed over at least one region of the first isolation region.

In some implementations, the first grid may have an inclined portion disposed in an upper portion of the first grid that is closer to the microlens as compared to a lower portion of the first grid.

In some implementations, the second inner isolation region may be formed at a position spaced apart by a certain space from the first inner isolation region.

In some implementations, the first grid may be disposed between one side of the second grid and another side of the second grid.

In some implementations, at least one region of the first grid may be disposed to overlap an upper region of the first inner isolation region and an upper region of the second inner isolation region.

In some implementations, the air layer may be a region that is free of light absorbing material that absorbs visible light

In another aspect, an image sensing device is provided to include: a pixel array that includes a plurality of unit pixels is disposed, a unit pixel in the pixel array may include a plurality of sub-pixels, a first isolation region may be disposed in an edge region of a sub-pixel, a second isolation region may extend from the first isolation region to a central portion of the sub-pixel, the second isolation region may include: a first inner isolation region protruding in a first direction from the first isolation region to the central portion of the sub-pixel, and a second inner isolation region formed on a same straight line as the first inner isolation region and protruding in a second direction from the first isolation region to the central portion of the sub-pixel, the second inner isolation region disposed to face the first inner isolation region, a third inner isolation region protruding in a third direction from the first isolation region to the central portion of the sub-pixel, the third direction being perpendicular to the first direction; and a fourth inner isolation region formed on a same straight line as the third inner isolation region and protruding in a fourth direction from the first isolation region to the central portion of the sub-pixel, the fourth inner isolation region disposed to face the third inner isolation region, a first grid may be formed in a first upper region that is located above a region between the first inner isolation region and the second isolation region, and in a second upper region that is located above a region between the third inner isolation region and the fourth inner isolation region, and the first grid may include an air layer.

In some implementations, the sub-pixel may include: the first inner isolation region; the second inner isolation region; the third inner isolation region; the fourth inner isolation region; a color filter formed over the first inner isolation region, the second inner isolation region, the third inner isolation region, and the fourth inner isolation region; and a microlens formed over the color filter, and the first grid may be formed in a central portion of the color filter.

In some implementations, a photodiode may be formed below the first grid.

In some implementations, a second grid may be disposed over at least one region of the first isolation region.

In some implementations, the second inner isolation region may be spaced apart by a certain space from the first inner isolation region.

In some implementations, the third inner isolation region may be spaced apart by a certain space from the fourth inner isolation region.

In some implementations, second grids may be formed at both sides of the first grid.

In some implementations, the first grid may be formed in a shape of a cross by having four portions extending in four different directions.

In some implementations, at least one region of the first grid may be formed to overlap the first inner isolation region, the second inner isolation region, the third inner isolation region, and the fourth inner isolation region.

In some implementations, the air layer may be free of light absorbing material that absorbs visible light

### BRIEF DESCRIPTION OF THE DRAWINGS

FIG. 1 is a block diagram of an image sensing device based on a first embodiment of the disclosed technology.

FIG. 2 is a view illustrating a pixel array based on a first embodiment of the disclosed technology.

FIG. 3 is a view illustrating a sub-pixel of a pixel array based on a first embodiment of the disclosed technology.

FIG. 4 is a cross-sectional view taken along line A-A′ of a sub-pixel based on a first embodiment of FIG. 3.

FIG. 5 is a cross-sectional view taken along line B-B′ of a sub-pixel based on a first embodiment of FIG. 3.

FIG. 6 is a view illustrating a structure of a first grid based on an embodiment of the disclosed technology.

FIG. 7 is a view illustrating a pixel array based on a second embodiment of the disclosed technology.

FIG. 8 is a view illustrating a sub-pixel of a pixel array based on a second embodiment of the disclosed technology.

FIG. 9 is a cross-sectional view taken along line C-C′ of a sub-pixel based on a second embodiment of FIG. 8.

FIG. 10 is a cross-sectional view taken along line D-D′ of a sub-pixel based on a second embodiment of FIG. 8.

FIG. 11 is a cross-sectional view taken along line E-E′ of a sub-pixel based on a second embodiment of FIG. 8.

### DETAILED DESCRIPTION

Features, and certain advantages in connection with specific implementations of the disclosed technology disclosed in this patent document are described by example embodiments with reference to the accompanying drawings.

In image sensing devices with a dual photodiode (2PD) and a quad photodiode (4PD), light incident to a microlens is scattered through a deep trench isolation (DTI) region, and enters each photodiode. In case of a small pixel, since an isolation region includes polysilicon (Poly Si), the incident light is scattered and absorbed in the isolation region at the same time, resulting in an optical loss.

In some implementations, by forming an air grid over an inner isolation region of a sub-pixel, an optical loss may be prevented from occurrence since incident light is scattered and absorbed in the inner isolation region at the same time due to the presence of this air grid.

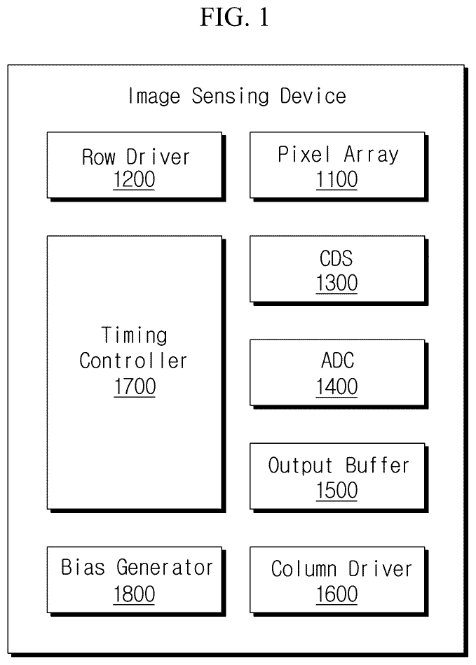

FIG. 1 is a block diagram of an image sensing device according to an embodiment.

Referring to FIG. 1, the image sensing device according to an embodiment may include a pixel array 1100, a row driver 1200, a correlated double sampler (CDS) 1300, an analog-digital converter (ADC) 1400, an output buffer 1500, a column driver 1600, a timing controller 1700, and a bias generator 1800. The components of the image sensing device illustrated are discussed by way of example only, and this patent document encompasses additions or omissions of components as necessary.

The pixel array 1100 may include a plurality of pixels arranged in a plurality of rows and a plurality of columns. In one embodiment, the plurality of pixels can be arranged in a two-dimensional pixel array including rows and columns. In another example, the plurality of unit imaging pixels can be arranged in a three-dimensional pixel array. The plurality of pixels may convert an optical signal into an electrical signal on a unit pixel basis or on a pixel group basis and the pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In one embodiment, the row driver 1200 may select at least one pixel arranged in at least one row of the pixel array 1100. The row driver 1200 may generate a row selection signal to select at least one row among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. At this time, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. A reference signal representing reset noise inherent in a pixel and an image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In some embodiments, the correlated double sampling (CDS) may remove the undesired offset value of pixels by comparing pixel output voltages obtained before and after photocharges generated by the pixels in response to the received incident light are accumulated in the sensing node so that only pixel output voltages based on the incident light can be measured. In one embodiment, the CDS 1300 may sequentially sample and hold the reference signal and the image signal, which are provided to each of a plurality of column lines from the pixel array 1100. Thus, the CDS 1300 may sample and hold the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 is used to convert CDS signals into digital signals for each of the columns and output the digital signal. In one embodiment, the ADC 1400 may be implemented as a ramp-compare type ADC. The ramp-compare type ADC may include a comparator circuit for comparing the analog pixel signal with a ramp signal that ramps up or down over time, and a counter that counts until the ramp signal matches the analog pixel signal. In one embodiment, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals corresponding to each of the columns into digital signals using the column counters. In another embodiment, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The output buffer 1500 may temporarily store the image data output from the ADC 1400 based on control signals of the timing controller 1700. The output buffer 1500 may serve as an interface to compensate for data rate differences or transmission (or processing) rate differences between the image sensing device and other devices.

The column driver 1600 may select a column of the output buffer 1500 based on a control signal from the timing controller 1700, and sequentially output the image data, which are temporarily stored in the selected column of the output buffer 1500. In one embodiment, upon receiving an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one among the row driver 1200, the CDS 1300, the ADC 1400, the output buffer 1500, the column driver 1600, and the bias generator 1800.

The timing controller 1700 may provide a clock signal required for the operations of the respective components of the image sensing device, a control signal for timing control, and address signals for selecting a row or column, a signal that controls a level of a bias voltage applied to the pixel array 1100, and the like to at least one among the row driver 1200, the CDS 1300, the ADC 1400, the output buffer 1500, the column driver 1600 and the bias generator 1800. In an embodiment of the present disclosure, the timing controller 1700 may include a logic control circuit, a phase lock loop (PLL) circuit, a timing control circuit, a communication interface circuit and others.

The bias generator 1800 may generate a bias voltage for suppressing a dark current generated in pixels of the pixel array 1100 and supply the generated bias voltage to the pixel array 1100.

The bias voltage may be determined during a wafer probe test of the image sensing device and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage stored in the OTP memory. According to an embodiment, the OTP memory may be included in the image sensing device, and in particular, may be included in the bias generator 1800.

According to an embodiment, the bias voltage may include a plurality of values.

For example, the plurality of values may respectively correspond to a plurality of operation modes of the image sensing device. The dark currents generated at low light and that generated at high light may be different from each other, and the bias voltage provided by the bias generator 1800 to effectively suppress the dark currents in each environment may vary depending on a mode.

In some implementations, the plurality of values may respectively correspond to a plurality of areas of the pixel array 1100. The dark currents generated may be different from each other according to positions of the pixel in the pixel array 1100, and the bias voltage provided by the bias generator 1800 to effectively suppress the dark current regardless of the position of the pixel may vary according to the area.

The bias voltage may be a negative voltage having a negative sign, but the present disclosure is not limited thereto.

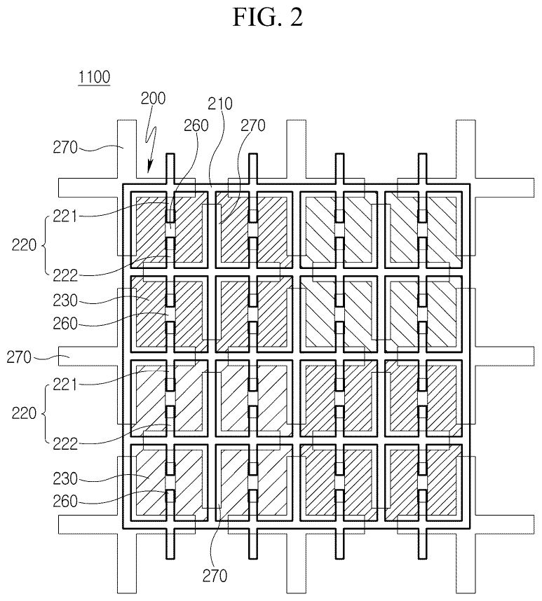

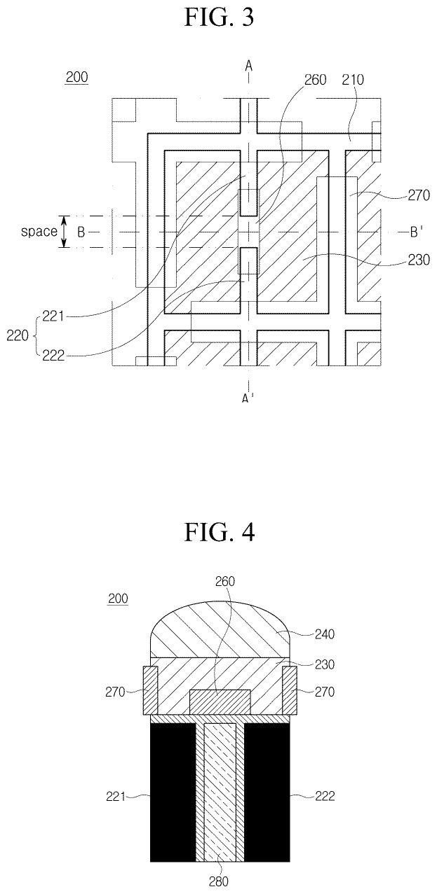

FIG. 2 is a view illustrating a pixel array according to a first embodiment, and FIG. 3 is a view illustrating a sub-pixel of the pixel array according to the first embodiment.

Referring to FIG. 2, the image sensing device according to an embodiment may be the image sensing device of a dual photodiode type (2PD).

In an embodiment, the pixel array 1100 may include a plurality of unit pixels, and each unit pixel may include four sub-pixels which include color filters of the same kinds, and two photodiodes may be formed below each of the color filter. The sub-pixels respond to incident light to produce sub-pixel signals that are associated with the pixel signal of the unit pixel. For example, the pixel signal generated by each unit pixel is a sum of the sub-pixel signals generated by sub-pixels within that unit pixel.

Referring to FIGS. 2 and 3, a first isolation region 210 may be formed in an edge region (a boundary region between sub-pixels 200) of the sub-pixel 200. In some implementation, in a plan view, the first isolation region 210 may be located on four sides of the sub-pixel 200. The first isolation region 210 may be formed in a shape of extending vertically from the surface of the substrate so as to prevent a crosstalk among neighboring sub-pixels 200, and may be formed, for example, through a deep trench isolation (DTI) process.

The first isolation region 210 may include at least one among a silicon oxynitride (SiON) layer, a silicon oxide (SiO) layer, a silicon nitride (SiN) layer, and/or polysilicon (Poly Si).

A second isolation region 220 may be formed on a side of the first isolation region 210, which is an inside of the sub-pixel. In a plan view, the second isolation region 220 may extend in a direction from the first isolation region 210 to a central portion of the sub-pixel 200.

The second isolation region 220 may be formed in a shape of extending vertically from the surface of the substrate so as to prevent a crosstalk among neighboring photodiodes and may be formed through the deep trench isolation (DTI) process.

The second isolation region 220 may include a silicon oxynitride (SiON) layer, a silicon oxide (SiO) layer, a silicon nitride (SiN) layer, and/or polysilicon (Poly Si).

In an embodiment, the second isolation region 220 may include a first inner isolation region 221, and a second inner isolation region 222.

The first inner isolation region 221 may protrude in a direction from one region of the first isolation region 210 to the central portion of the sub-pixel 200.

The second inner isolation region 222 may be formed on the same straight line as the first inner isolation region 221, and may protrude in the direction from another region of the first isolation region 210 (a region opposite to a region in which the first inner isolation region 221 is formed) to the central portion of the sub-pixel 200.

A first grid 260 may be formed in an upper region that is located above a region between the first inner isolation region 221 and the second inner isolation region 222. In an embodiment, the first grid 260 may be formed such that the first grid 260 has at least one region that vertically overlaps the first inner isolation region 221 and/or the second inner isolation region 222. For example, a portion of the first grid 260 is disposed over the first inner isolation region 221 and/or another portion of the first grid 260 is disposed over the second inner isolation region 222.

In an embodiment, the first grid 260 may be structured to include a section of a hollow region or enclosure that provides an air layer (air region) by not including a light absorbing material that absorbs visible light. Thus, this hollow region that provides the air layer of the first grid 260 is free of the light absorbing material. The refractive index of the first grid 260 may be 1.

Since the first grid 260 is formed in the upper region that is located above a region between the first inner isolation region 221 and the second inner isolation region 222, the optical loss may be prevented from occurrence as the incident light is scattered and absorbed into the first inner isolation region 221 and the second inner isolation region 222 at the same time. The first grid 260 makes the incident light from the color filter 230 layer enter each photodiode, and prevents the incident light from reaching the first inner isolation region 221 and the second inner isolation region 222, thereby reducing the optical loss caused by the light absorption.

In an embodiment, a second grid 270 may be formed over the first isolation region 210. In an embodiment, the second grid 270 may be formed over at least one region of the first isolation region 210. In an embodiment, the second grid 270 may include an air layer (air region) that is free of light absorption material that absorbs visible light. In an embodiment, a refractive index of the second grid 270 may be 1.

Since the second grid 270 is formed over the first isolation region 210, the incident light is prevented from reaching the first isolation region 210, thereby reducing the optical loss due to the light absorption.

In an embodiment, the second inner isolation region 222 may be formed at a position spaced apart by a certain space from the first inner isolation region 221. The certain space may have various values depending on settings.

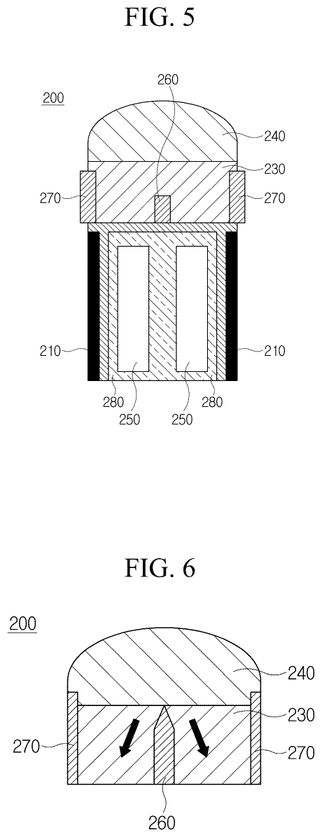

FIG. 4 is a cross-sectional view taken along line A-A′ of the sub-pixel according to the first embodiment of FIG. 3. FIG. 5 is a cross-sectional view taken along line B-B′ of the sub-pixel according to the first embodiment of FIG. 3.

Referring to FIGS. 4 and 5, the sub-pixel 200 may include the first isolation region 210, the first inner isolation region 221, the second inner isolation region 222, the color filter 230, a microlens 240, a photodiode 250, the first grid 260, the second grid 270, and a substrate 280.

The first isolation region 210 may be formed between neighboring sub-pixels 200.

The first inner isolation region 221 and the second inner isolation region 222 may be formed below the color filter 230.

The color filter 230 may be formed over the substrate 280, may filter and pass certain visible light from the incident light which enters the microlens 240. In some implementations, the color filter 230 may include one color filter among a blue color filter which passes only blue light from the visible light, a green color filter which passes only green light from the visible light, and a red color filter which passes only red light from the visible light.

The microlens 240 may be formed over the color filter 230, and may serve to collect the incident light entered from the outside.

The photodiode 250 may be formed in an inner region of the substrate 280 and may be formed below the first grid 260, and a n-type impurity region and a p-type impurity region may be vertically stacked in the photodiode 250. The n-type impurity region and the p-type impurity region may be formed through an ion injection process. The photodiode 250 is described as one example of the photoelectric conversion element which is configured to convert the incident light into electrical charges. In some implementation, the photoelectric conversion element can be as a phototransistor, a photogate, or a combination thereof, etc.

The first grid 260 may be formed in a central region of the color filter 230. The first grid 260 may include air layer (air region) therein. In an embodiment, the refractive index of the first grid 260 may be less than that of the color filter 230.

The first grid 260 may make incident light enter each photodiode 250 from the color filter 230, and prevent the incident light from reaching the first inner isolation region 221 and the second inner isolation region 222, thereby reducing the optical loss occurring due to light absorption.

The first grid 260 may be formed between one side of the second grid 270 and another side of the second grid 270. The second grids 270 may be formed at both sides of the first grid 260.

The second grid 270 may be formed over the first isolation region 210.

In an embodiment, the second grid 270 may include a metal layer, or an air layer.

In an embodiment, the second grid 270 may include the metal layer that includes a first metal layer (not illustrated) and a second metal layer (not illustrated) formed over the first metal layer (not illustrated). In an embodiment, the first metal layer (not illustrated) may include a titanium nitride layer (TiN). In an embodiment, the second metal layer (not illustrated) may include tungsten (W).

In the example, the second grid 270 may be structured to include a section of a hollow region that provides an air layer including an air region not having light absorbing material that absorbs visible light. Thus, this hollow region that provides the air layer of the second grid 270 is free of the light absorbing material.

The substrate 280 may include a silicon (Si) material in a single-crystalline state.

FIG. 6 is a view illustrating a structure of the first grid according to an embodiment.

Referring to FIG. 6, in an embodiment, the first grid 260 may have an inclined portion. The inclined portion is disposed closer to the microlens 240 as compared to the remaining portion of the first grid. The first grid 260 may be disposed between a first surface and a second surface of the color filter 230, the second surface opposite to the first surface. When the microlens 240 is disposed on the first surface of the color filter 230, the inclined portion of the first grid 260 is closer to the first surface of the color filter 230 than the second surface of the color filter 230. In an embodiment, the first grid 260 may have a shape that narrows upward, e.g., the direction toward the microlens 240. The first grid 260 may serve to isolate the incident light from the dual photodiode (2PD), or the quad photodiode (4PD). The first grid 260 may make the incident light enter each photodiode from the dual photodiode (2PD), or the quad photodiode (4PD).

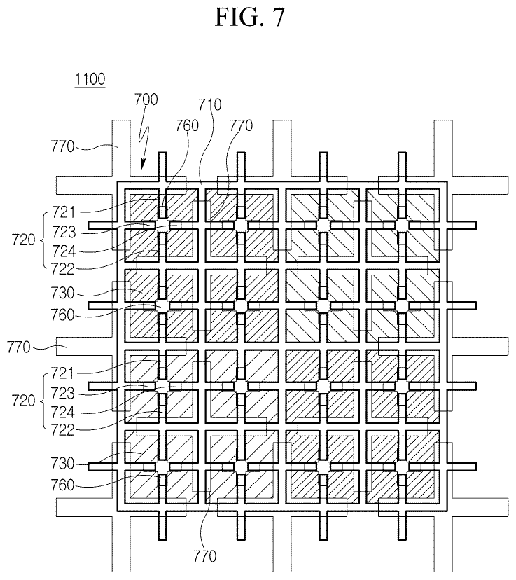

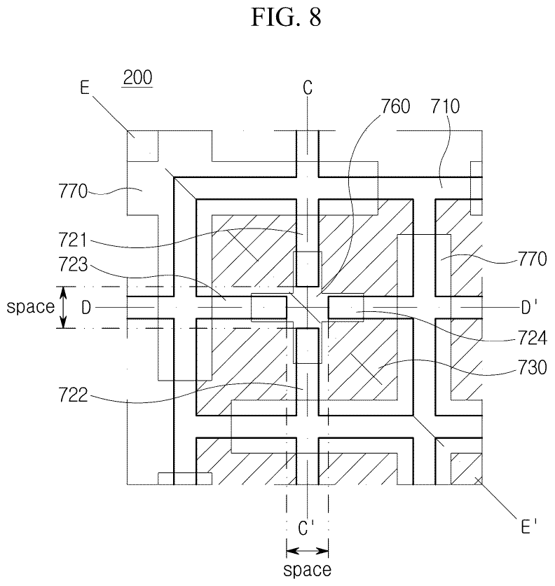

FIG. 7 is a view illustrating the pixel array according to a second embodiment. FIG. 8 is a view for describing the sub-pixel of the pixel array according to the second embodiment.

Referring to FIG. 7, the image sensing device according to an embodiment may be the image sensing device of the quad photodiode (4PD) type.

In an embodiment, the pixel array 1100 may include a plurality of unit pixels, and each unit pixel may include four sub-pixels which include color filters of the same kinds, and two photodiodes may be formed below each of the color filter.

Referring to FIGS. 7 and 8, a first isolation region 710 may be formed in an edge region (a boundary region between sub-pixels 700) of the sub-pixel 700. In some implementation, in a plan view, the first isolation region 710 may be located on four sides of the sub-pixel 700. The first isolation region 710 may be formed in a shape of extending vertically from the surface of the substrate so as to prevent a crosstalk among neighboring sub-pixels 700, and may be formed, for example, through a deep trench isolation (DTI) process.

The first isolation region 710 may include at least one among a silicon oxynitride (SiON) layer, a silicon oxide (SiO) layer, a silicon nitride (SiN) layer, and/or polysilicon (Poly Si).

A second isolation region 720 may be formed on a side of the first isolation region 710, which is an inside of the sub-pixel. In a plan view, the second isolation region 720 may extend in a direction from the first isolation region 710 to a central portion of the sub-pixel 700.

The second isolation region 720 may be formed in a shape of extending vertically from the surface of the substrate so as to prevent a crosstalk among neighboring photodiodes and may be formed through the deep trench isolation (DTI) process.

The second isolation region 720 may include a silicon oxynitride (SiON) layer, a silicon oxide (SiO) layer, a silicon nitride (SiN) layer, and/or polysilicon (Poly Si).

In an embodiment, the second isolation region 720 may include a first inner isolation region 721, a second inner isolation region 722, a third inner isolation region 723, and a fourth inner isolation region 724.

The first inner isolation region 721 may protrude in a first direction from one region of the first isolation region 710 to the central portion of the sub-pixel 700.

The second inner isolation region 722 may be formed on the same straight line as the first inner isolation region 721, and may protrude in a second direction to the central portion of the sub-pixel 700 from another region of the first isolation region 710 (a region opposite to a region in which the first inner isolation region 721 is formed). The second direction is the opposite direction to the first direction.

The third inner isolation region 723 may protrude in a third direction from the first isolation region 710 to the central portion of the sub-pixel 700, the third direction perpendicular to the first direction along which first isolation region 710 protrudes.

The fourth inner isolation region 724 may be formed on the same straight line as the third inner isolation region 723 and protrude in a fourth direction from the first isolation region 710 to the central portion of the sub-pixel 700. The fourth direction is the opposite direction of the third direction. The fourth inner isolation region 724 is disposed to face the third inner isolation region 723.

A first grid 760 may be formed in an upper region that is located above an area between the first inner isolation region 721 and the second isolation region 722, and in an upper region that is located above an area between the third inner isolation region 723 and the fourth inner isolation region 724. In an embodiment, the first grid 760 may be formed in a way that at least one region of the first grid 760 overlaps the first inner isolation region 721, the second inner isolation region 722, the third inner isolation region 723, and/or the fourth inner isolation region 724. For example, a first portion of the first grid 760 is disposed over the first inner isolation region 721, a second portion of the first grid 260 is disposed over the second inner isolation region 722, a third portion of the first grid 760 is disposed over the third inner isolation region 723, and/or a fourth portion of the first grid 760 is disposed over the fourth inner isolation region 724.

In an embodiment, the first grid 760 may be structured to include a section of a hollow region that provides an air layer not having light absorbing material that absorbs visible light. Thus, this hollow region that provides the air layer of the first grid 760 is free of the light absorbing material.

Since the first grid 760 is formed in the upper region that is located above an area between the first inner isolation region 721 and the second inner isolation region 722, and the upper region that is located above an area between the third inner isolation region 723 and the fourth inner isolation region 724, the optical loss may be prevented from occurrence as the incident light is scattered and absorbed into the first inner isolation region 721, the second inner isolation region 722, the third inner isolation region 723, and the fourth inner isolation region 724 at the same time. The first grid 760 makes the incident light from a color filter 730 layer enter each photodiode, and prevents the incident light from reaching the first inner isolation region 221, the second inner isolation region 222, the third inner isolation region 723, and the fourth inner isolation region 724, thereby reducing the optical loss caused by the light absorption.

In an embodiment, a second grid 770 may be formed over the first isolation region 710. In an embodiment, the second grid 770 may be formed over at least one region of the first isolation region 710. In an embodiment, the second grid 770 may include an air layer (air region) not having light absorption material. Thus, the air layer is free of light absorption material.

Since the second grid 770 is formed over the first isolation region 710, the incident light is prevented from reaching the first isolation region 710, thereby reducing the optical loss due to the light absorption.

In an embodiment, the second inner isolation region 722 may be formed at a position spaced apart by a certain space from the first inner isolation region 721, and the fourth inner isolation region 724 may be formed at a position spaced apart by a certain space from the third inner isolation region 723. The certain space may have various values depending on settings.

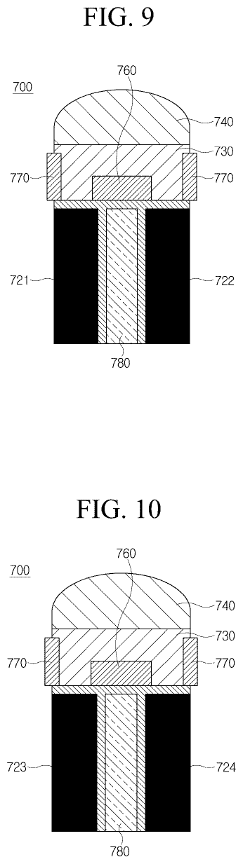

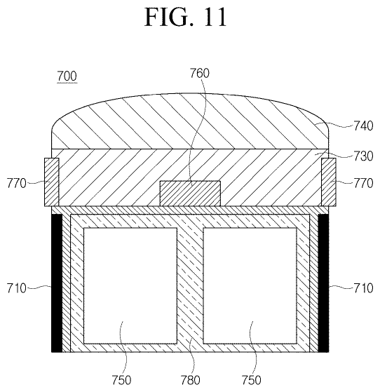

FIG. 9 is a cross-sectional view taken along line C-C′ of the sub-pixel according to the second embodiment of FIG. 8. FIG. 10 is a cross-sectional view taken along line D-D′ of the sub-pixel according to the second embodiment of FIG. 8. FIG. 11 is a cross-sectional view taken along line E-E′ of the sub-pixel according to the second embodiment of FIG. 8.

Referring to FIGS. 9 and 11, the sub-pixel 700 may include the first isolation region 710, the first inner isolation region 721, the second inner isolation region 722, the third inner isolation region 723, the fourth inner isolation region 724, the color filter 730, a microlens 740, a photodiode 750, the first grid 760, the second grid 770, and a substrate 780.

The first isolation region 710 may be formed between neighboring sub-pixels 700.

The first inner isolation region 721, the second inner isolation region 722, the third inner isolation region 723, and the fourth inner isolation region 724 may be formed below the color filter 730.

The color filter 730 may be formed over the substrate 780, may filter and pass certain visible light from the incident light which enters the microlens 740. The color filter 730 may include one color filter among a blue color filter which passes only blue light from the visible light, a green color filter which passes only green light from the visible light, and a red color filter which passes only red light from the visible light.

The microlens 740 may be formed over the color filter 730, and may serve to collect the incident light entered from the outside.

The photodiode 750 may be formed in an inner region of the substrate 780 and may be formed below the first grid 760, and a n-type impurity region and a p-type impurity region may be vertically stacked in the photodiode 750. The n-type impurity region and the p-type impurity region may be formed through an ion injection process. The photodiode 750 is described as one example of the photoelectric conversion element which is configured to convert the incident light into electrical charges. In some implementation, the photoelectric conversion element can be as a phototransistor, a photogate, or a combination thereof, etc.

The first grid 760 may be formed in a central region of the color filter 730. The first grid 760 may include air therein. In an embodiment, the refractive index of the first grid 760 may be less than that of the color filter 730.

The first grid 760 may make incident light enter each photodiode 750 from the color filter 730, and prevent the incident light from reaching the first inner isolation region 721, the second inner isolation region 722, the third inner isolation region 723, and the fourth inner isolation region 724, thereby reducing the optical loss occurring due to light absorption.

The first grid 760 may be formed between one side of the second grid 270 and another side of the second grid 770. The second grids 770 may be formed at both sides of the first grid 760.

The first grid 760 may be formed in a shape of a cross. The first grid 760 may have four portions extending in four different directions from the center of the substrate.

The second grid 770 may be formed over the first isolation region 710.

In an embodiment, the second grid 770 may include a metal layer, or an air layer.

In an embodiment, the second grid 770 may include the metal layer that includes a first metal layer (not illustrated) and a second metal layer (not illustrated) formed over the first metal layer (not illustrated). In an embodiment, the first metal layer (not illustrated) may include a titanium nitride layer (TiN). In an embodiment, the second metal layer (not illustrated) may include tungsten (W).

In an embodiment, the second grid 770 may be structured to include a section of a hollow region that provides the air layer including an air region not having light absorbing material that absorbs visible light. Thus, this hollow region that provides the air layer of the second grid 270 is free of the light absorbing material.

The substrate 780 may include a silicon (Si) material in a single-crystalline state.

While various embodiments have been described above, variations and improvements of the disclosed embodiments and other embodiments may be made based on what is described or illustrated in this document.

I/we claim:

1. An image sensing device, comprising:
a pixel array that includes a plurality of unit pixels,
wherein a unit pixel in the pixel array includes a plurality of sub-pixels,
wherein a first isolation region is disposed in an edge region of a sub-pixel,
wherein a second isolation region extends from the first isolation region to a central portion of the sub-pixel,
wherein the second isolation region comprises:
a first inner isolation region protruding in a first direction from one region of the first isolation region to the central portion of the sub-pixel, and
a second inner isolation region formed on a same straight line as the first inner isolation region and protruding in a second direction from another region of the first isolation region to the central portion of the sub-pixel,
wherein a first grid is formed in an upper region that is located above a region between the first inner isolation region and the second inner isolation region, and
wherein the first grid comprises an air layer.

2. The image sensing device of claim 1,
wherein the sub-pixel comprises:
the first inner isolation region,
the second inner isolation region,
a color filter formed over the first inner isolation region and the second inner isolation region, and
a microlens formed over the color filter, and
wherein the first grid is formed in a central region of the color filter.

3. The image sensing device of claim 2,
wherein a photodiode is disposed below the first grid.

4. The image sensing device of claim 2,
wherein a second grid is disposed over at least one region of the first isolation region.

5. The image sensing device of claim 2,
wherein the first grid has an inclined portion disposed in an upper portion of the first grid that is closer to the microlens as compared to a lower portion of the first grid.

6. The image sensing device of claim 1,
wherein the second inner isolation region is formed at a position spaced apart by a certain space from the first inner isolation region.

7. The image sensing device of claim 2,
wherein the first grid is disposed between one side of the second grid and another side of the second grid.

8. The image sensing device of claim 2,
wherein at least one region of the first grid is disposed to overlap an upper region of the first inner isolation region and an upper region of the second inner isolation region.

9. The image sensing device of claim 1, wherein the air layer is a region that is free of light absorbing material that absorbs visible light.

10. An image sensing device, comprising:
a pixel array that includes a plurality of unit pixels,
wherein a unit pixel in the pixel array includes a plurality of sub-pixels,
wherein a first isolation region is disposed in an edge region of a sub-pixel,
wherein a second isolation region extends from the first isolation region to a central portion of the sub-pixel,
wherein the second isolation region comprises:
a first inner isolation region protruding in a first direction from the first isolation region to the central portion of the sub-pixel, and
a second inner isolation region formed on a same straight line as the first inner isolation region and protruding in a second direction from the first isolation region to the central portion of the sub-pixel, the second inner isolation region disposed to face the first inner isolation region,
a third inner isolation region protruding in a third direction from the first isolation region to the central portion of the sub-pixel, the third direction being perpendicular to the first direction; and
a fourth inner isolation region formed on a same straight line as the third inner isolation region and protruding in a fourth direction from the first isolation region to the central portion of the sub-pixel, the fourth inner isolation region disposed to face the third inner isolation region,
wherein a first grid is formed in a first upper region that is located above a region between the first inner isolation region and the second isolation region, and in a second upper region that is located above a region between the third inner isolation region and the fourth inner isolation region, and
wherein the first grid comprises an air layer.

11. The image sensing device of claim 10,
wherein the sub-pixel comprises:
the first inner isolation region;
the second inner isolation region;
the third inner isolation region;
the fourth inner isolation region;
a color filter formed over the first inner isolation region, the second inner isolation region, the third inner isolation region, and the fourth inner isolation region; and
a microlens formed over the color filter, and
wherein the first grid is formed in a central portion of the color filter.

12. The image sensing device of claim 11,
wherein a photodiode is formed below the first grid.

13. The image sensing device of claim 11, further comprising:
a second grid disposed over at least one region of the first isolation region.

14. The image sensing device of claim 10,
wherein the second inner isolation region is spaced apart by a certain space from the first inner isolation region.

15. The image sensing device of claim 10,
wherein the third inner isolation region is spaced apart by a certain space from the fourth inner isolation region.

16. The image sensing device of claim 11, further comprising:
second grids formed at both sides of the first grid.

17. The image sensing device of claim 16,
wherein the first grid is formed in a shape of a cross by having four portions extending in four different directions.

18. The image sensing device of claim 11,
wherein at least one region of the first grid is formed to overlap the first inner isolation region, the second inner isolation region, the third inner isolation region, and the fourth inner isolation region.

19. The image sensing device of claim 11, wherein the air layer is free of light absorbing material that absorbs visible light.
